(19) United States
(12) Patent Application Publication
(10) Pub. No.: US 2013/0279130 A1
(43) Pub. Date: Oct. 24, 2013

(54) ELECTRONIC DEVICE

(71) Applicant: FUJITSU MOBILE COMMUNICATIONS LIMITED, Kawasaki-shi (JP)

(72) Inventors: Akio Ihara, Hachioji (JP); Hiroyuki Dai, Musashino (JP); Satoru Noma, Hino (JP); Shingo Tokunaga, Kokubunji (JP)

(73) Assignee: FUJITSU MOBILE COMMUNICATIONS LIMITED, Kawasaki-shi (JP)

(21) Appl. No.: 13/858,377

(22) Filed: Apr. 8, 2013

(30) Foreign Application Priority Data
Apr. 19, 2012 (JP) 2012-095734

(51) Int. Cl. H05K 5/06

(52) U.S. Cl. CPC H05K 5/061
USPC 361/752

(57) ABSTRACT

An electronic device includes a casing, a substrate, an electronic component, and an elastic member. The substrate is arranged inside the casing. The electronic component is arranged on the substrate. The elastic member includes a recessed portion formed to house the electronic component and a convex portion protruding toward the casing side over an entire circumference of the electronic component and being formed in an outer circumference side from the recess unit. The elastic member is compressed between the casing and the substrate.

### CROSS-REFERENCE TO RELATED APPLICATION

This application is based upon and claims the benefit of priority of the prior Japanese Patent Application No. 2012-095734 filed on Apr. 19, 2012, the entire contents of which are incorporated herein by reference.

### FIELD

The embodiments discussed herein are related to an electronic device including an elastic member.

### BACKGROUND

Conventionally, an electronic device including a casing to which electronic components are mounted, a cover attachable to or detachable from the casing, and a conductive waterproof packing member provided on the cover has been known.

In addition, portable wireless equipment that has a circular elastic member sandwiched between a first case and a second case, both of which are casings, has been known.
Patent Document 1: Japanese Laid-Open Patent Publication No. 2011-166668
Patent Document 2: Japanese Laid-Open Patent Publication No. 2011-24022

### SUMMARY

According to an aspect of the embodiments, an electronic device includes a casing, a substrate, an electronic component, and an elastic member. The substrate is arranged inside the casing. The electronic component is arranged on the substrate. The elastic member includes a recessed portion formed to house the electronic component and a convex portion protruding toward the casing side over an entire circumference of the electronic component and being formed in an outer circumference side from the recess unit. The elastic member is compressed between the casing and the substrate.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF DRAWINGS

FIG. 1 is a front view illustrating the electronic device according to the present embodiment.

FIG. 2 is a cross-sectional view taken along a line II-II in FIG. 1.

FIG. 3 includes (a) a front view, (b) a top view, (c) a right side view, (d) a bottom view, and (e) a back view which illustrate an elastic member in the present embodiment.

FIG. 4 is a cross-sectional view taken along a line IV-IV in FIG. 3.

FIG. 5A is a front view illustrating a substrate 20 in the present embodiment.

FIG. 5B is a perspective view illustrating a substrate 20 in the present embodiment.

FIG. 6 is a perspective view illustrating a substrate in the first modification of the present embodiment.

FIG. 7 is a cross-sectional view illustrating an elastic member in the second modification of the present embodiment.

FIG. 8 is a cross-sectional view to explain an airtight structure of the reference technology.

### DESCRIPTION OF EMBODIMENTS

In an electronic device, a space outside the casing in which electronic components such as a thermo-hygro sensor and a microphone are arranged is used for measuring outer air or for securing acoustic properties, whereas a space inside the casing is hermetically sealed by an elastic member.

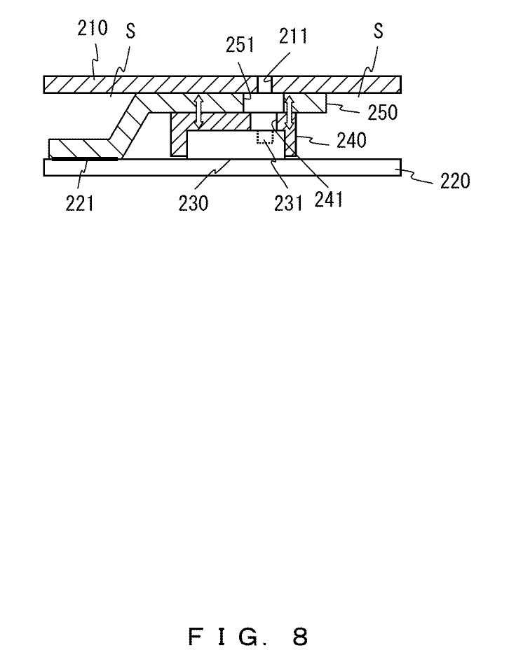

FIG. 8 is a cross-sectional view to describe an airtight structure of a reference technology.

As illustrated in FIG. 8, a through-hole 211, which faces a detector 231 of an electronic component 230 described above, is formed on a casing 210.

A substrate 220 is arranged inside the casing 210. The substrate 220 has a ground 221 of the electronic circuit formed in the substrate 220.

The electronic component 230 is arranged on the substrate 220. The electronic component 230 has a detector 231.

An elastic member 240 has a through-hole 241 formed on it. This through-hole 241 faces/is oriented toward the detector 231 and communicates with the through-hole 211. The elastic member 240 hermetically seals a space S inside the casing 210 when being compressed between the casing 210 and the electronic component 230.

Note that copper tape 250 is arranged between the elastic member 240 and the casing 210. This copper tape 250 is used for short-circuiting to the ground 221 so as to prevent damage in the electronic component 230 caused by static electricity.

In the above-described airtight structure, because the elastic member 240 is compressed between the electronic component 230 and the casing 210, variations in production such as solder cracking in the electronic component 230 at the time of mounting and misalignment of the mounting position of the electronic component 230 directly cause variability in an sealing pressure that is created by the elastic member 240.

In addition, when a portion facing the outside of the casing such as the detector 231 is not positioned at the center of the electronic component 230, the sealing pressure varies.

Furthermore, it is more difficult to secure airtightness in the space S inside the casing because of the surface pressure between the electronic component 230 and the casing 210 as the electronic component 230 becomes smaller.

In the following description, an electronic device according to the present embodiment is described with reference to drawings.

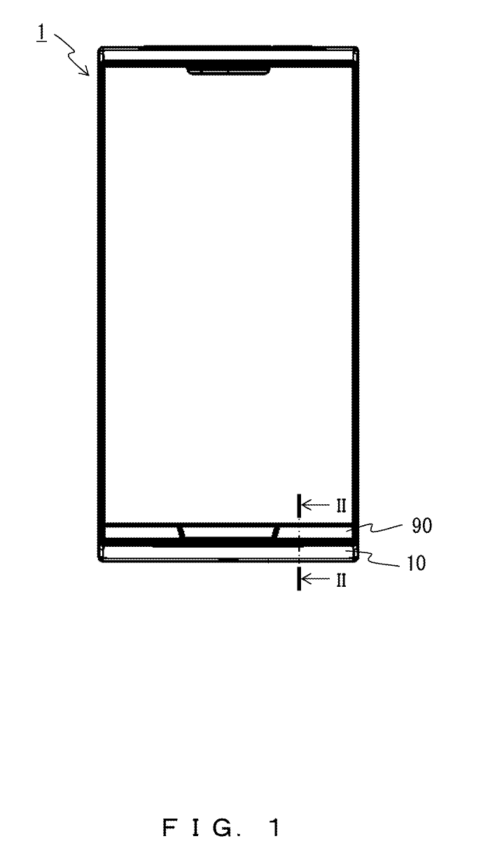

FIG. 1 is a front view illustrating the electronic device according to the present embodiment.

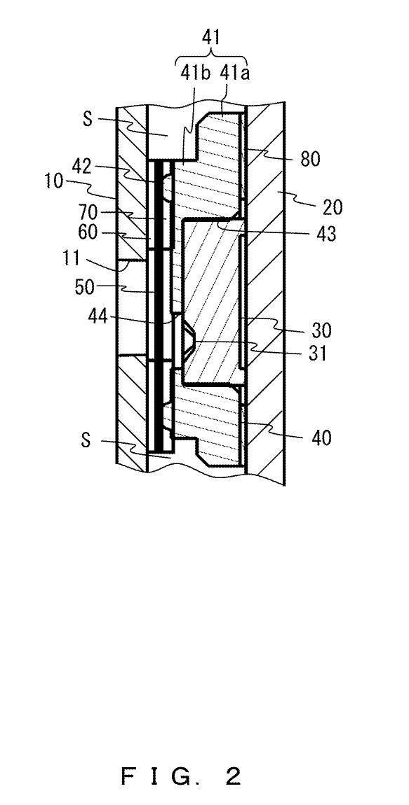

FIG. 2 is a cross-sectional view taken along a line II-II in FIG. 1.

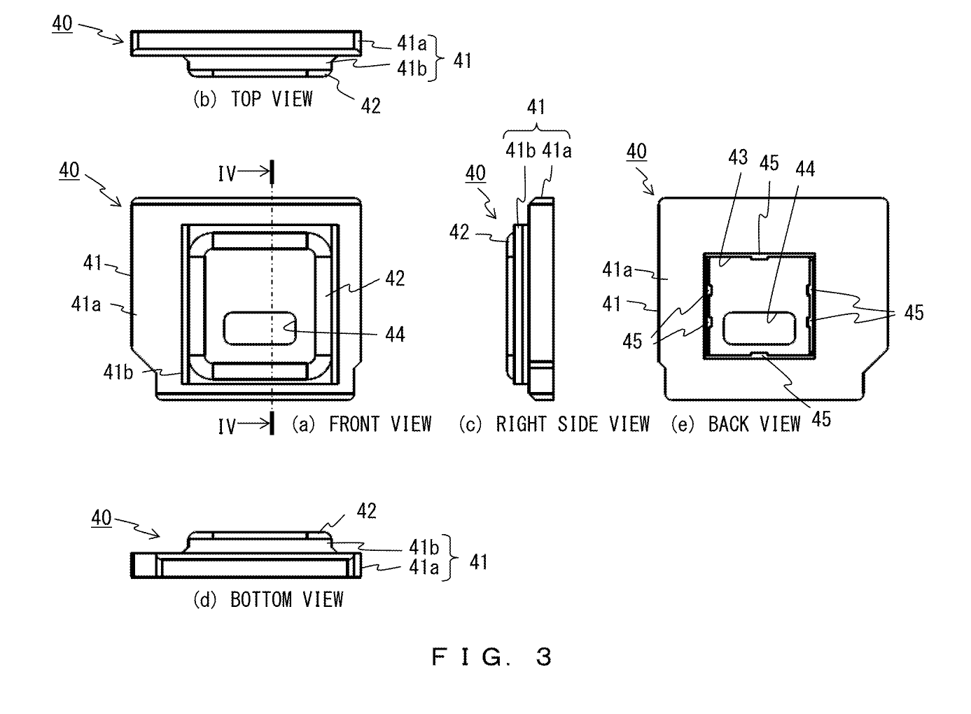

FIG. 3 includes (a) a front view, (b) a top view, (c) a right side view, (d) a bottom view, and (e) a back view which illustrate an elastic member in the present embodiment.

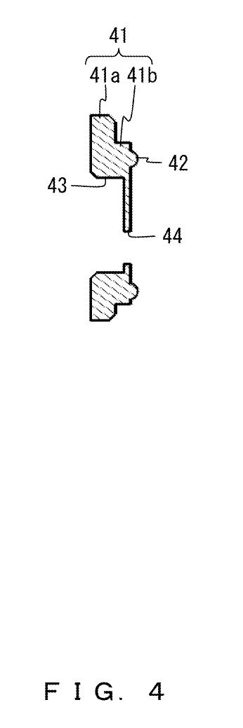

FIG. 4 is a cross-sectional view taken along a line IV-IV in FIG. 3.

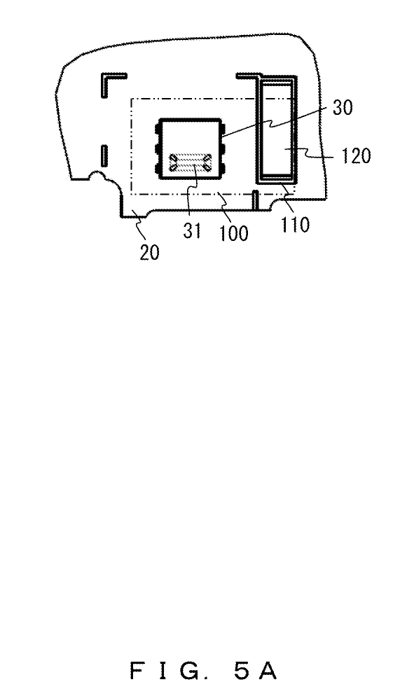

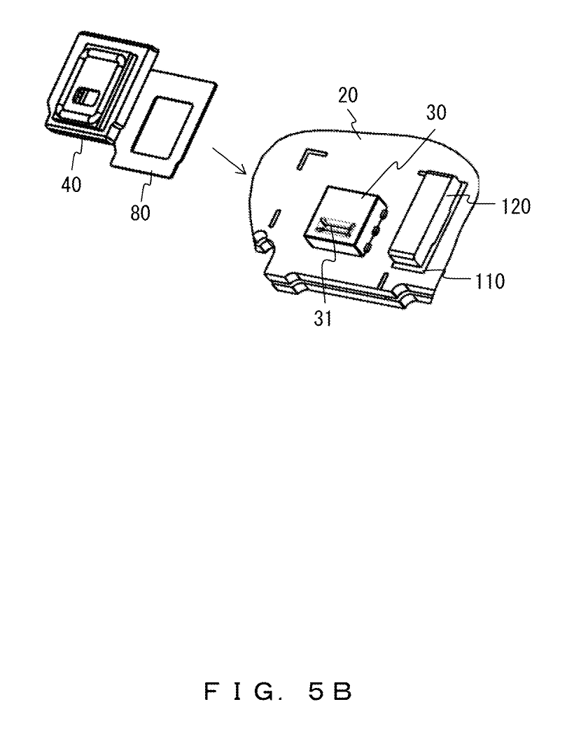

FIG. 5A and FIG. 5B are a front view and a perspective view illustrating a substrate 20 in the present embodiment.

An electronic device 1 illustrated in FIG. 1 is, for example, a portable electronic device such as a mobile phone.

As illustrated in FIG. 1 to FIG. 5B, the electronic device 1 includes a casing 10, a substrate 20, an electronic component 30, an elastic member 40, a waterproof sheet 50, a double-faced adhesive tape 60 for the waterproof sheet, an elastic sheet 70, a double-faced adhesive tape 80 for the elastic member, and a key switch 90.

The casing 10 is an exterior component of the electronic device 1, but some components such as the key switch 90 may be arranged outside of the casing 10. As illustrated in FIG. 2, a through-hole 11, which faces a detector 31 of the electronic component 30 described later, is formed on the casing 10. In the present embodiment, the through-hole 11 of the casing 10 is provided, for example, inside the key switch 90.

The substrate 20 is arranged inside the casing 10.

The electronic component 30 is arranged on the substrate 20. The electronic component 30 is a thermo-hygro sensor, for example, but may be another electronic component such as a microphone. The electronic component 30 includes a detector 31 that is an example of a portion facing/oriented toward the outside of the casing 10.

The elastic member 40 include a base 41, convex portions 42, a recessed portion 43, a through-hole 44, and protrusions 45 as illustrated in FIG. 3 and FIG. 4. The elastic member 40 hermetically seals an inner space S in the casing 10 illustrated in FIG. 2 as the elastic member 49 being compressed between the casing 10 and the substrate 20. Note that the inner space S is a portion of the space between the casing 10 and the substrate 20 which is located at least around the elastic member 40.

For example, the elastic member 40 is made of integrally molded rubber. The elastic member 40 may be formed from a conductive material, which is described later in detail. As an example, a possible conductive material is a material with a value of electric resistance of 10⁷Ω·cm or less.

The base 41 includes a substrate-side base 41a that has an approximately rectangular shape from the front view and a casing-side base 41b that has an approximately rectangular shape from the front view and is smaller than the substrate-side base 41a. The substrate-side base 41a and the casing-side base 41b do not have to be separated, and the size of the base 41 may be the same on the substrate 20 side and the casing 10 side.

The convex portions 42 are positioned all around the electronic component 30 and protrude from the casing-side base 41b toward the casing 10. Each of the convex portions 42 has an approximately rectangular frame from the front view.

The recessed portion 43 has an opening facing the substrate 20 side to house the electronic component 30.

The convex portions 42 are formed on the outer circumference side of the recessed portion 43. In other words, a portion in the back of the convex portions 42 is located around the recessed portion 43.

The through-hole 44 is provided on the bottom of the recessed portion 43 so as to penetrate the casing-side base 41b. The through-hole 44 faces/is oriented toward the detector 31 of the electronic component 30 and communicates with the through-hole 11 of the casing 10 through the waterproof sheet 50.

As illustrated in FIG. 3(e), the protrusions 45 are formed to protrude toward the electronic component 30 side in such a manner that any two opposing sides of the four sides at the opening end of the recessed portion 43 will each have two protrusions and each of the rest of the four sides has one protrusion. The protrusions 45 are in abutment with the outer periphery of the electronic component 30 to hold the electronic component 30.

The waterproof sheet 50 keeps liquid from entering from the through-hole 11 of the casing 10 but allows gas to enter. As illustrated in FIG. 2, the waterproof sheet 50 is attached to the surface of the casing 10 on the substrate 20 side by the double-faced adhesive tape 60 for the waterproof sheet so that it is arranged between the casing 10 and the convex portions 42. On the other side of the double-faced adhesive tape 60 for the waterproof sheet across the waterproof sheet 50, the elastic sheet 70 is arranged. This elastic sheet 70 lies between the base 41 and the waterproof sheet 50 and is pressed by the convex portions 42.

As illustrated in FIG. 2 and FIG. 5B, the double-faced adhesive tape 80 for the elastic member adheres the elastic member 40 to the substrate 20 around the electronic component 30.

Copper tape (an example of a grounding sheet) 100 may be arranged between the casing 10 and the convex portions 42 of the elastic member 40. This copper tape 100 prevents damage to the electronic component 30 caused by static electricity by short-circuiting to a ground 110 the electronic circuit formed on the substrate 20, as illustrated by a two-dot dash line in FIG. 5A. The ground 110 does not face the elastic member 40, but is provided immediately below a gasket 120 provided on the substrate 20 and between the substrate 20 and the casing 10.

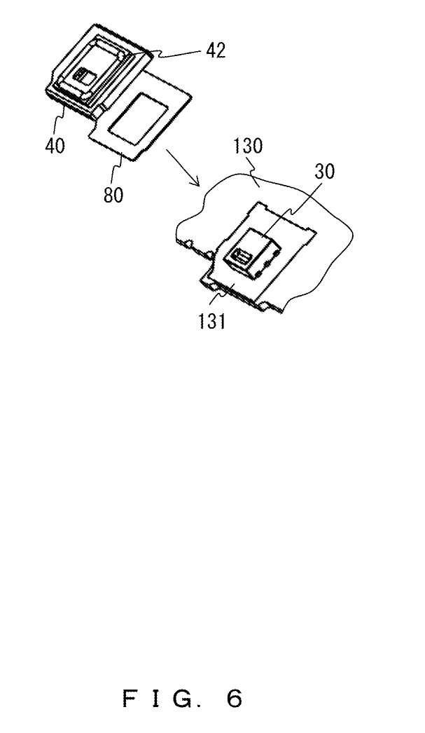

FIG. 6 is a perspective view illustrating a substrate 130 in a first modification of the embodiment.

As illustrated in FIG. 6, on the substrate 130 in the first modification in which the electronic component 30 is arranged, a ground 131 may be arranged so as to face the elastic member 40.

The ground 131 may be formed so as to face a portion in the back of at least the convex portions 42 of the elastic member 40.

The ground 131 may also be provided over the entire circumference of the electronic component 30 in the substrate 130.

As a result of the ground 131 facing the elastic member 40, static electricity directly flows from the elastic member 40 to the ground 131 without the need to use the copper tape 100. It is also possible to short-circuit the elastic member 40 to the ground 131 even if the elastic member 40 is not formed from a conductive material. However, it is particularly effective when the elastic member 40 is formed from a conductive material.

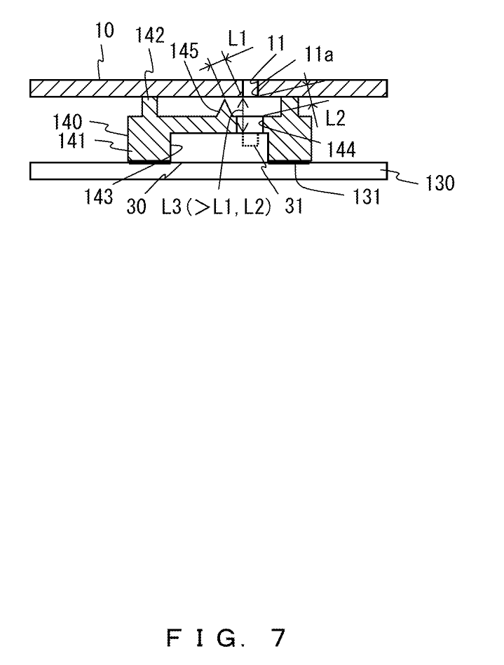

FIG. 7 is a cross-sectional view of an elastic material 140 in the second modification of the embodiment.

In this modification, similarly to the first modification, the substrate 130 has the ground 131 arranged so as to face a portion in the back of the convex portions 142 of the elastic member 140. However, similarly to the substrate 20 illustrated in FIG. 2, the ground 131 that faces the elastic member 40 can be omitted.

As illustrated in FIG. 7, similarly to the elastic member 40 in FIG. 2, the elastic member 140 has a base 141, convex portions 142, a recessed portion 143, and a through-hole 144.

In this modification, a protrusion 145 that protrudes toward the side of the casing 10 is formed on the elastic member 140. The protrusion 145 is formed to have a triangular pyramid shape, for example, near the through-hole 144.

In the present modification, through-holes 11 and 41, which communicate with each other and face the electronic component 30, are provided to the casing 10 and the elastic member 140, respectively.

A space L3 between an end 11a of the through-hole 11 of the casing 10 exists on the electronic component 30 side and the electronic component 30 is larger than a space L1 that is between the electronic component side end 11a and the protrusion 145 (L3>L1).

When the protrusion 145 is not provided, the space L3 between the electronic component side end 11a of the through-hole 11 of the casing 10 and the electronic component 30 is larger than a space L2 that is between the electronic component side end 11a and the elastic member 140 (the base 141 closest to the electronic component side end 11a) (L3>L2). This relationship (L3>L2) is true in the elastic component 40 in FIG. 2.

As a result of the above relationship (L3>L1 or L3>L2) being satisfied, the static electricity in the casing 10 flows from the through-hole 11 to the elastic member 40 rather than to the electronic component 30, and it eventually flows to the ground 131.

In the above-described embodiment, a recess unit 43 that houses the electronic component 30 and a convex portion 42 that protrudes toward the side of the casing 10 over the entire circumference of the electronic component 30 are formed on the elastic member 40. The elastic member 40 hermetically seals a space S inside the casing 10 when being compressed between the casing 10 and the substrate 20.

For that reason, comparing a case in which the elastic member 40 is compressed between the electronic component 30 and the casing 10, the above-described embodiment can control the variations in production of the electronic component 30 that cause variability in the sealing pressure of the elastic member 40. When a component facing outside the casing such as a detector 31 is not located at the center of the electronic component 30 or when the electronic component 30 is small, airtightness in the space S inside the casing between the substrate 20 and the casing 10 can be ensured.

Thus, according to the present embodiment, it is possible to securely and hermetically seal the space S inside the casing 10.

Moreover, even if there is a component that generates high-temperature heat in the space S inside the casing 10, because the elastic member 40 controls the influence of the temperature or humidity in the space S inside the casing 10 on the electronic component 30, functions of the electronic component 30, e.g., a thermo-hygro sensor, can be securely fulfilled.

Furthermore, at the time of displacement of the casing 10, the elastic member 40 is compressed so that damage to the electronic component 30 can be prevented. It is also possible to omit members to reduce stress on the electronic component 30 such as ribs protruding from the casing 10 toward the substrate 20 side around the electronic component 30 to prevent damage to the electronic component 30 caused by compression of the elastic member 40 so that the mounting area of the substrate 20 can be secured.

Note that when the elastic member 40 can keep the airtightness even under pressure in a waterproofed state (1 atmosphere or higher), it is possible to omit an operation to cover the through-hole 11 of the casing 10 with tape to adopt an inspection technique such as outside pressure difference measurement at the time of a waterproof testing of the entire electronic device 1. For that reason, the number of steps of the test can be reduced.

Note that in the present embodiment (the first modification and the second modification), the ground 131 of the electronic circuit formed on the substrate 130 is formed at a position facing the elastic member 40 or 140. In such a case, the elastic member 40, which can be compressed, securely prevents damage in the electronic component 30 caused by static electricity and can more certainly ensure the mounting area of the substrate 130 compared with a case in which the ground 110 does not face the elastic member 40, which is illustrated in FIG. 5A and FIG. 5B.

In addition, when the ground 131 faces a portion in the back of at least the convex portion 42 or 142 of the elastic member 40 or 140, it is possible to securely prevent the damage to electronic components caused by static electricity in the portion at the back of the convex portion 42 that is a compressed portion of the elastic member 40 or 140. Additionally, the mounting area of the substrate 130 can be further ensured.

In the present embodiment, when the ground 131 is provided over the entire circumference of the electronic component 30 in the substrate 130, it is possible to more securely prevent damage to the electronic component 30 caused by static electricity.

Moreover, in the present embodiment, when the elastic member 40 or 140 is formed from a conductive material, damage to the electronic component 30 caused by static electricity can be securely prevented.

In the present embodiment, the casing 10 and the elastic member 40 respectively have through-holes 11 and 41 which communicate with each other and face the electronic component 30. The space L3 between an end 11a of the through-hole 11 of the casing 10 on the electronic component 30 side and the electronic component 30 is larger than the space L2 that is between the electronic component side end 11a and the elastic member 140. In such a case, the static electricity in the casing 10 flows from the through-hole 11 to the elastic member 40 rather than to the electronic component 30. As a result, damage to the electronic component 30 caused by the static electricity can be prevented.

Furthermore, in the present embodiment (second modification), the protrusion 145 that protrudes toward the casing 10 side is formed on the elastic member 140, and the space L3 between the above-described end 11a of the through-hole 11 and the electronic component 30 is larger than the space L1 between the end 11a and the protrusion. In this case, damage to the electronic component 30 caused by the static electricity can be securely prevented.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that the various changes, substitutions, and alterations could be made hereto without departing from the spirit and scope of the invention.

What is claimed is:

1. An electronic device comprising:
a casing;
a substrate arranged inside the casing;
an electronic component arranged on the substrate; and
an elastic member compressed between the casing and the substrate, the elastic member including a recessed portion formed to house the electronic component and a convex portion protruding toward the casing side over an entire circumference of the electronic component and being formed in an outer circumference side from the recess unit.

2. The electronic device of claim 1, wherein
the substrate includes a ground of an electronic circuit formed on the substrate and disposed at a position facing the elastic member.

3. The electronic device according to claim 2, wherein
the ground faces a portion in at least a back of the convex portion of the elastic member.

4. The electronic device according to claim 2, wherein
the ground is provided over an entire circumference of the electronic component in the substrate.

5. The electronic device according to claim 1, wherein
the elastic material is formed from a conductive material.

6. The electronic device according to claim 1, wherein
the casing and the elastic member include a through-hole communicating with one another and facing the electronic component, and
a space between an end of the through hole of the casing at the electronic device side and the electronic component is larger than a space between the end and the elastic member.

7. The electronic device according to claim 6, wherein
the elastic member includes a protrusion that protrudes toward the casing side; and
the space between the end and the electronic component is larger than the space between the end and the protrusion.

8. The electronic device according to claim 1, wherein
the electronic component is a thermo-hygro sensor.
